(19) United States
(12) Patent Application Publication
(10) Pub. No.: US 2024/0304682 A1
(43) Pub. Date: Sep. 12, 2024

(54) SEMICONDUCTOR DEVICE AND METHOD OF MANUFACTURING SEMICONDUCTOR DEVICE

(71) Applicant: ROHM CO., LTD., Kyoto (JP)

(72) Inventors: Kosaku ADACHI, Kyoto (JP); Shota IZUMI, Kyoto (JP)

(73) Assignee: ROHM CO., LTD., Kyoto (JP)

(21) Appl. No.: 18/596,305

(22) Filed: Mar. 5, 2024

(30) Foreign Application Priority Data
Mar. 6, 2023 (JP) 2023-034062

(51) Int. Cl. H01L 29/40; H01L 23/522; H01L 29/423; H01L 29/78

(52) U.S. Cl. CPC H01L 29/404; H01L 23/5226; H01L 29/401; H01L 29/407; H01L 29/423; H01L 29/7823

(57) ABSTRACT

A semiconductor device includes: a semiconductor chip including first and second main surfaces; and an element isolation portion partitioning a device region at the first main surface. The element isolation portion includes: a first isolation trench formed at the first main surface; an isolation insulating film at an inner wall of the first isolation trench; and an isolation conductor buried in the first isolation trench via the isolation insulating film. The isolation conductor includes: a first isolation conductor formed at a central portion of the first isolation trench; and a second isolation conductor formed at a side of the first isolation conductor with an inner insulating film interposed therebetween. The second isolation conductor includes an inner wall in contact with the inner insulating film and an outer wall, wherein a top of the second isolation conductor includes an inclined wall inclined downward from the outer wall toward the inner wall.

### CROSS-REFERENCE TO RELATED APPLICATION

This application is based upon and claims the benefit of priority from Japanese Patent Application No. 2023-034062, filed on Mar. 6, 2023, the entire contents of which are incorporated herein by reference.

### TECHNICAL FIELD

The present disclosure relates to a semiconductor device and a method of manufacturing the semiconductor device.

### BACKGROUND

In the related art, a semiconductor device which includes an element isolation portion including a DTI (Deep Trench Isolation) structure is disclosed. The element isolation portion includes a trench formed at a main surface of a semiconductor chip, an insulating film covering a side surface of the trench, and polysilicon buried in the trench with the insulating film interposed therebetween. The polysilicon is electrically connected to a high-concentration impurity region via a bottom wall of the trench.

### BRIEF DESCRIPTION OF DRAWINGS

The accompanying drawings, which are incorporated in and constitute a part of the specification, illustrate embodiments of the present disclosure.

FIG. 1 is a schematic plan view of a semiconductor device according to a first embodiment of the present disclosure.

FIG. 2 is an enlarged view of region II shown in FIG. 1.

FIG. 3 is a view showing a cross-section taken along line III-III shown in FIG. 2.

FIG. 4 is an enlarged cross-sectional view of a main part of a structure shown in FIG. 3.

FIG. 5 is an enlarged view of a portion surrounded by two-dot chain line V in FIG. 4.

FIG. 6A is a view corresponding to FIG. 4, and shows a part of a process of manufacturing the semiconductor device according to the first embodiment of the present disclosure.

FIG. 6B is a view showing a next step of FIG. 6A.

FIG. 6C is a view showing a next step of FIG. 6B.

FIG. 6D is a view showing a next step of FIG. 6C.

FIG. 6E is a view showing a next step of FIG. 6D.

FIG. 6F is a view showing a next step of FIG. 6E.

FIG. 6G is a view showing a next step of FIG. 6F.

FIG. 6H is a view showing a next step of FIG. 6G.

FIG. 6I is a view showing a next step of FIG. 6H.

FIG. 6J is a view showing a next step of FIG. 6I.

FIG. 6K is a view showing a next step of FIG. 6J.

FIG. 6L is a view showing a next step of FIG. 6K.

FIG. 7 is an enlarged cross-sectional view of a main part of a semiconductor device according to a second embodiment of the present disclosure.

FIG. 8 is a view for explaining a modification of an arrangement pattern of contact electrodes shown in FIG. 2.

FIG. 9 is a view showing a cross-section taken along line IX-IX shown in FIG. 8.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, embodiments of the present disclosure will be described in detail with reference to the accompanying drawings.

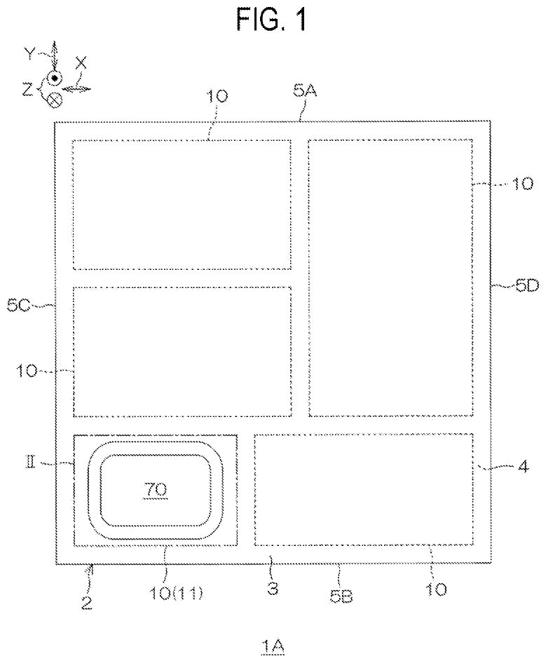

FIG. 1 is a schematic plan view of a semiconductor device 1A according to a first embodiment of the present disclosure.

Referring to FIG. 1, the semiconductor device 1A includes a semiconductor chip 2 having a rectangular parallelepiped shape. In this embodiment, the semiconductor chip 2 includes a Si (silicon) chip. The semiconductor chip 2 has a first main surface 3 on one side, a second main surface 4 on the other side, and first to fourth side surfaces 5A to 5D connecting the first main surface 3 and the second main surface 4.

The first main surface 3 and the second main surface 4 are formed in a quadrangular shape in a plan view when viewed from a normal direction Z thereof (hereinafter simply referred to as “a plan view”). The normal direction Z is also a thickness direction of the semiconductor chip 2. The first side surface 5A and the second side surface 5B extend in a first direction X along the first main surface 3 and face each other in a second direction Y that intersects (specifically, is perpendicular to) the first direction X. The third side surface 5C and the fourth side surface 5D extend in the second direction Y and face each other in the first direction X.

The semiconductor device 1A includes a plurality of device regions 10 formed at the first main surface 3. The plurality of device regions 10 are regions in which various functional devices are formed using inner regions of the semiconductor chip 2. The plurality of device regions 10 are spaced apart from the first to fourth side surfaces 5A to 5D in a plan view and are each compartmentalized at an inner portion of the first main surface 3. The number, arrangement, and shape of device regions 10 are all arbitrary, and are not limited to a specific number, arrangement, and shape.

The plurality of functional devices may each include at least one selected from the group of a semiconductor switching device, a semiconductor rectifying device, and a passive device. The semiconductor switching device may include at least one selected from the group of JFET (Junction Field Effect Transistor), MISFET (Metal Insulator Semiconductor Field Effect Transistor), BJT (Bipolar Junction Transistor), and IGBT (Insulated Gate Bipolar Junction Transistor).

The semiconductor rectifying device may include at least one selected from the group of a pn junction diode, a pin junction diode, a Zener diode, a Schottky barrier diode, and a fast recovery diode. The passive device may include at least one selected from the group of a resistor, a capacitor, an inductor, and a fuse. In this embodiment, the plurality of device regions 10 include at least one transistor region 11.

The transistor region 11 is a region where a plurality of transistor elements are formed. A current flows in the transistor region 11 in a lateral direction of the semiconductor chip 2 when source-drain of the semiconductor device 1A is in a conductive state (on state). The transistor region 11 has, for example, a quadrangular shape in a plan view.

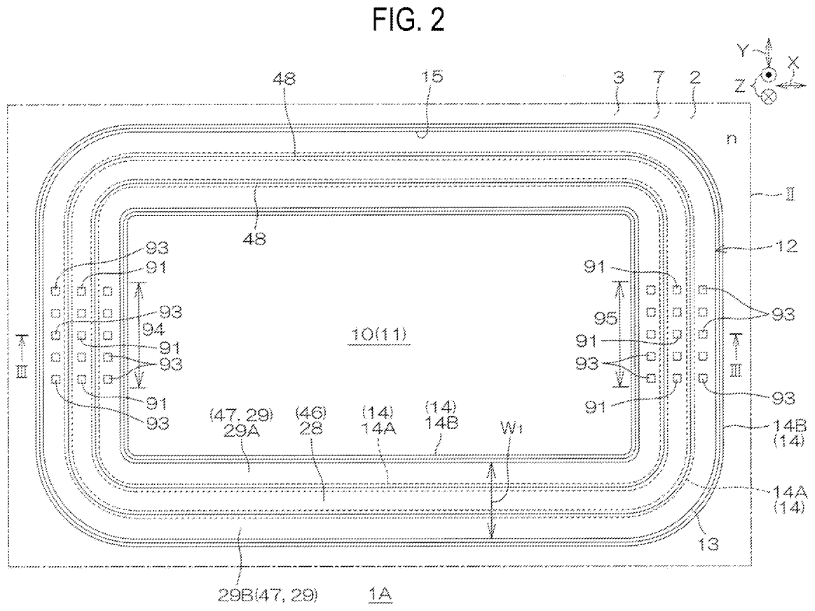

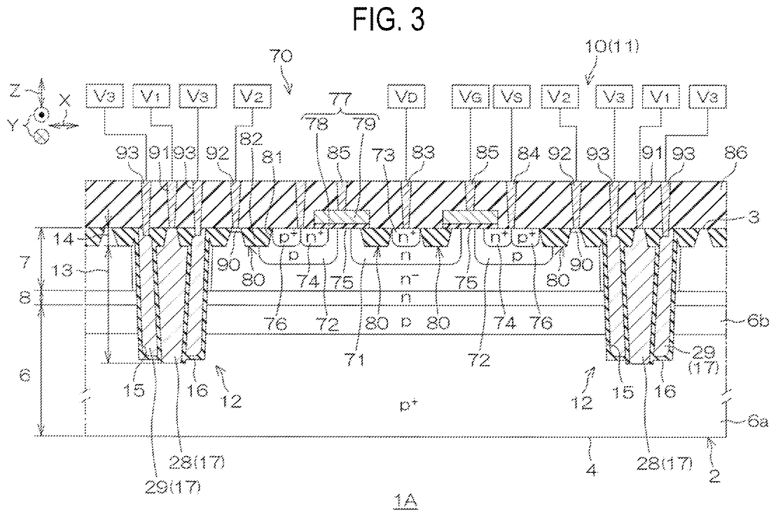

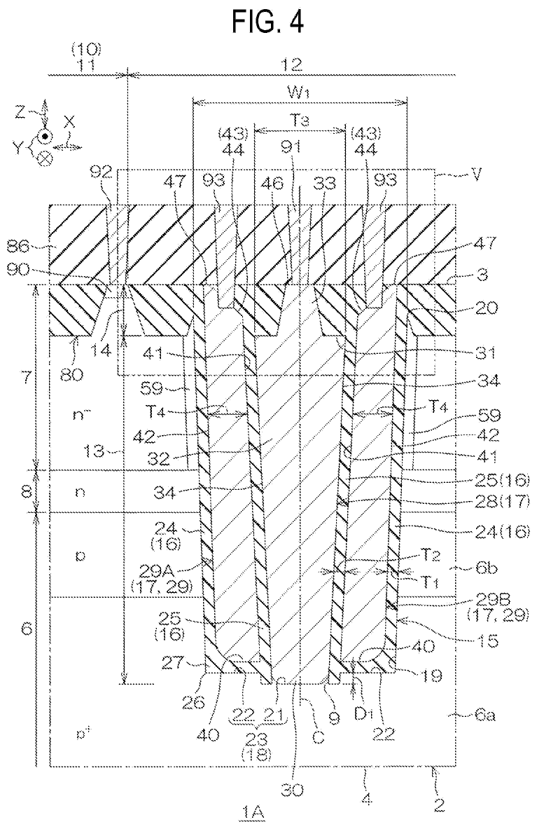

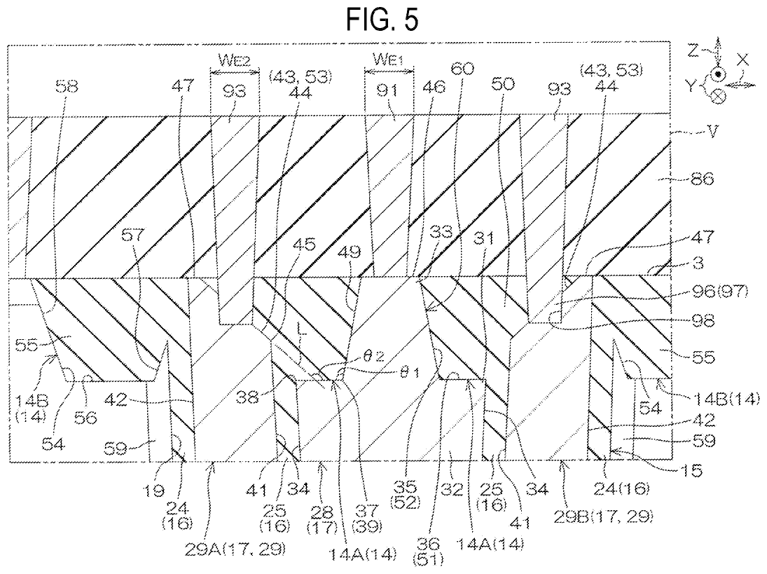

FIG. 2 is an enlarged view of region II shown in FIG. 1. FIG. 3 is a view showing a cross-section taken along line III-III shown in FIG. 2. FIG. 4 is an enlarged cross-sectional view of a main part of a structure shown in FIG. 3. FIG. 5 is an enlarged view of a portion surrounded by two-dot chain line V in FIG. 4.

Referring to FIGS. 3 and 4, the semiconductor chip 2 includes a p-type (first conductivity type) first impurity region 6 formed at a region near the second main surface 4. The first impurity region 6 may also be referred to as a “base region.” The first impurity region 6 extends in a layered form along the second main surface 4 and is exposed from portions of the second main surface 4 and the first to fourth side surfaces 5A to 5D. The first impurity region 6 has a concentration gradient in which a p-type impurity concentration near the first main surface 3 is lower than a p-type impurity concentration near the second main surface 4. Specifically, the first impurity region 6 has a laminated structure including a p-type high-concentration region 6a and a p-type low-concentration region 6b stacked in this order from the second main surface 4. Although an outline of the second main surface 4 is not shown in the enlarged view of FIG. 4, for the sake of convenience of explanation, a place of the semiconductor chip 2 closest to the second main surface 4 is shown as the second main surface 4.

The high-concentration region 6a has a relatively high p-type impurity concentration. A p-type impurity concentration of the high-concentration region 6a may be 1×10¹⁷ cm⁻³ or more and 1×10²⁰ cm⁻³ or less. The high-concentration region 6a may include boron (B) as the p-type impurity. The high-concentration region 6a may have a thickness of 50 μm or more and 500 μm or less. In this embodiment, the high-concentration region 6a includes a p-type semiconductor substrate (Si substrate).

The low-concentration region 6b has a lower p-type impurity concentration than the high-concentration region 6a and is laminated on the high-concentration region 6a. A p-type impurity concentration of the low-concentration region 6b may be 1×10¹⁴ cm⁻³ or more and 1×10¹⁷ cm⁻³ or less. The low-concentration region 6b may contain boron (B) as the p-type impurity. The low-concentration region 6b has a thickness thinner than the thickness of the high-concentration region 6a. The thickness of the low-concentration region 6b may be 1 μm or more and 20 μm or less. In this embodiment, the low-concentration region 6b includes a p-type epitaxial layer (Si epitaxial layer).

Referring to FIGS. 3 and 4, the semiconductor chip 2 includes an n-type (second conductivity type) second impurity region 7 formed in a region near the first main surface 3. The second impurity region 7 extends in a layered form along the first main surface 3 and is exposed from portions of the first main surface 3 and the first to fourth side surfaces 5A to 5D. An n-type impurity concentration of the second impurity region 7 may be 1×10¹⁴ cm⁻³ or more and 1×10¹⁷ cm⁻³ or less. The second impurity region 7 may have a thickness of 5 μm or more and 30 μm or less. The second impurity region 7 may have a uniform n-type impurity concentration in the thickness direction, or may have a concentration gradient in which the n-type impurity concentration increases toward the first main surface 3. The second impurity region 7 may include an n-type epitaxial layer (Si epitaxial layer).

The semiconductor chip 2 includes an n-type (second conductivity type) buried region 8 buried between the first impurity region 6 and the second impurity region 7. In other words, the first impurity region 6, the buried region 8, and the second impurity region 7 are laminated in this order from the second main surface 4. The buried region 8 is electrically connected to the first impurity region 6 and the second impurity region 7. The buried region 8 extends in a layered form along the second impurity region 7. The buried region 8 is exposed from portions of the first to fourth side surfaces 5A to 5D. The n-type impurity concentration of the buried region 8 is higher than the n-type impurity concentration of the second impurity region 7 and may be, for example, 1×10¹⁶ cm⁻³ or more and 1×10²¹ cm⁻³ or less. The buried region 8 may have a thickness of 0.1 μm or more and 5 μm or less. The buried region 8 may include an n-type epitaxial layer (Si epitaxial layer).

Referring to FIGS. 2 to 4, the semiconductor chip 2 includes an element isolation portion 12 formed near the first main surface 3 and partitioning the transistor region 11. The element isolation portion 12 has an annular shape, specifically a quadrangular annular shape, in a plan view. More specifically, the element isolation portion 12 has a quadrangular annular shape having corner portions (four corners) curved in an arc-shape in a plan view.

The element isolation portion 12 includes a first trench structure 13 and a second trench structure 14 formed near the first main surface 3 with respect to the first trench structure 13.

Referring to FIG. 2, both the first trench structure 13 and the second trench structure 14 have an annular shape, specifically a quadrangular annular shape, in a plan view. Some of a plurality of second trench structures 14 overlap the first trench structure 13 in a plan view. The second trench structures 14 overlapping the first trench structure 13 are formed over a top of the first trench structure 13. In FIG. 2, the second trench structures 14 overlapping the first trench structure 13 are shown in broken lines.

The first trench structure 13 includes an isolation trench 15, an isolation insulating film 16, and an isolation conductor 17.

Referring to FIG. 2, the isolation trench 15 (an example of a first isolation trench) is formed near the first main surface 3 so as to partition the transistor region 11. In this embodiment, the isolation trench 15 has an annular shape (in this embodiment, a quadrangular annular shape) in a plan view. More specifically, the isolation trench 15 has corner portions (four corners) curved in an-arc shape in a plan view.

Referring to FIG. 4, the isolation trench 15 penetrates the second impurity region 7 and the buried region 8 to reach the first impurity region 6. A bottom 18 of the isolation trench 15 is located in the first impurity region 6. The bottom 18 of the isolation trench 15 may also be referred to as a bottom wall of the isolation trench 15. Specifically, the isolation trench 15 extends from the first main surface 3 toward the second main surface 4 so as to reach the high-concentration region 6a of the first impurity region 6, and penetrates the second impurity region 7, the buried region 8, and the low-concentration region 6b of the first impurity region 6.

The isolation trench 15 is formed in a tapered shape whose width increases from the bottom 18 toward a top 20 in a cross-sectional view. Therefore, the width of the isolation trench 15 (a distance between a pair of opposing side wall 19 in a cross-sectional view) increases continuously from the bottom 18 toward the top 20. The isolation trench 15 has a first width W₁ at the top 20. The first width W₁ is a width in a direction perpendicular to a direction in which the isolation trench 15 extends in a plan view. The first width W₁ may be 0.5 μm or more and 10 μm or less. The first width W₁ is preferably 2 μm or more and 5 μm or less. A side wall 19 of the isolation trench 15 may provide a flat or substantially flat surface from the bottom 18 to the top 20.

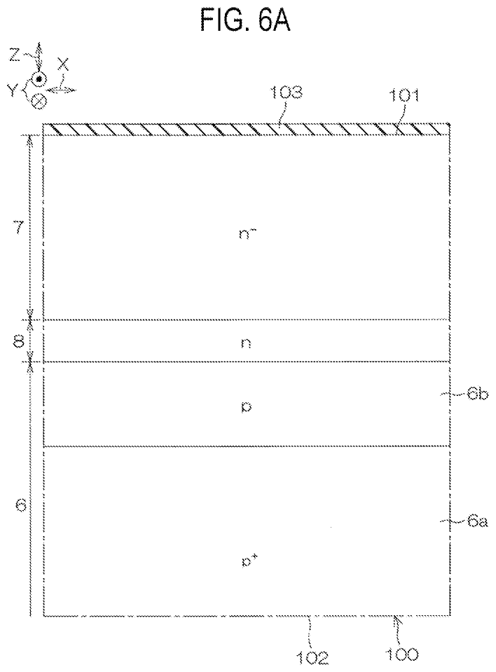

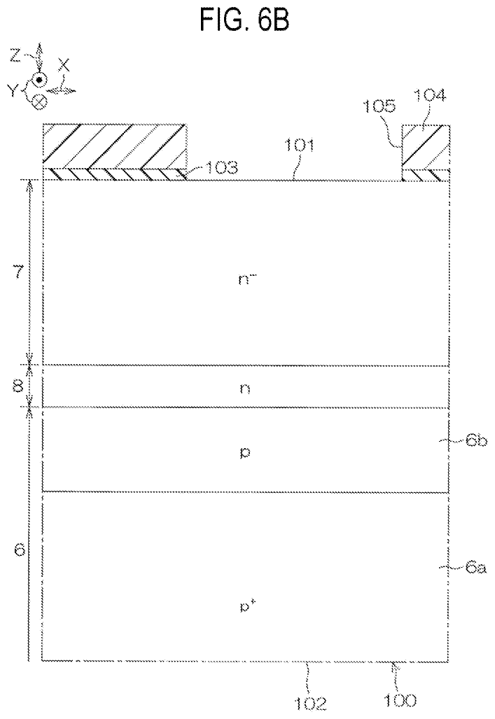

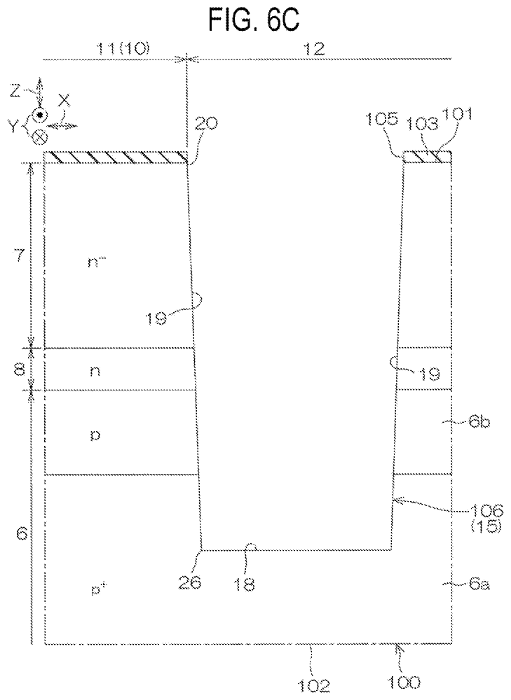

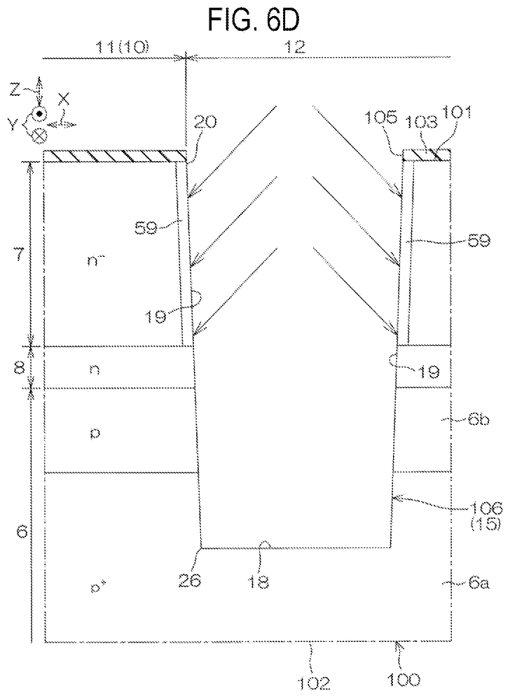

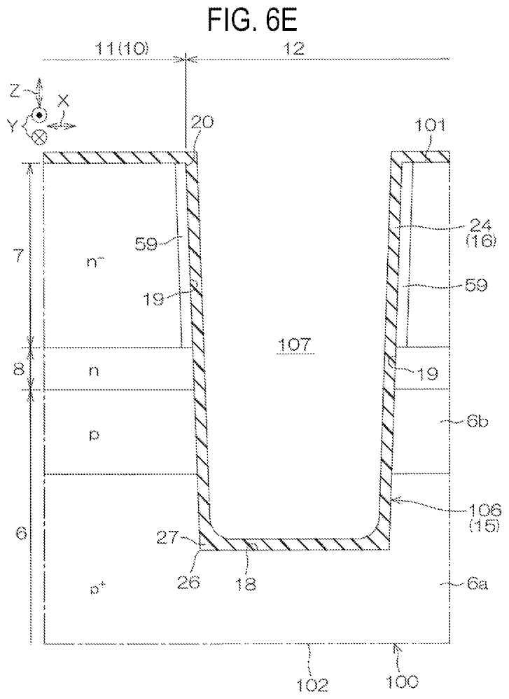

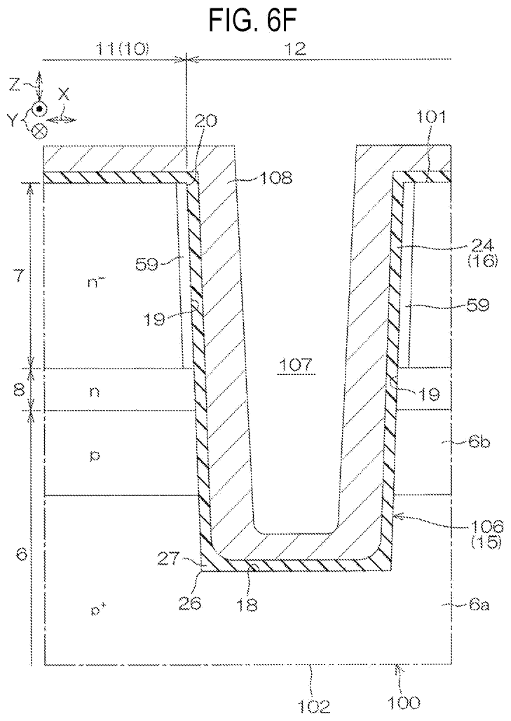

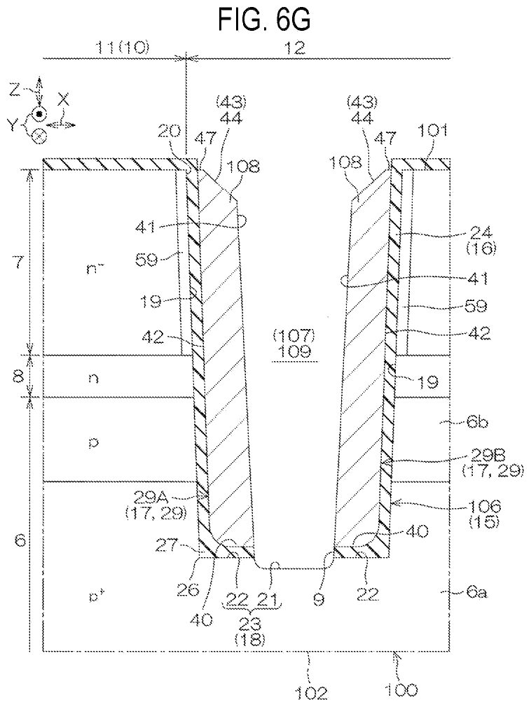

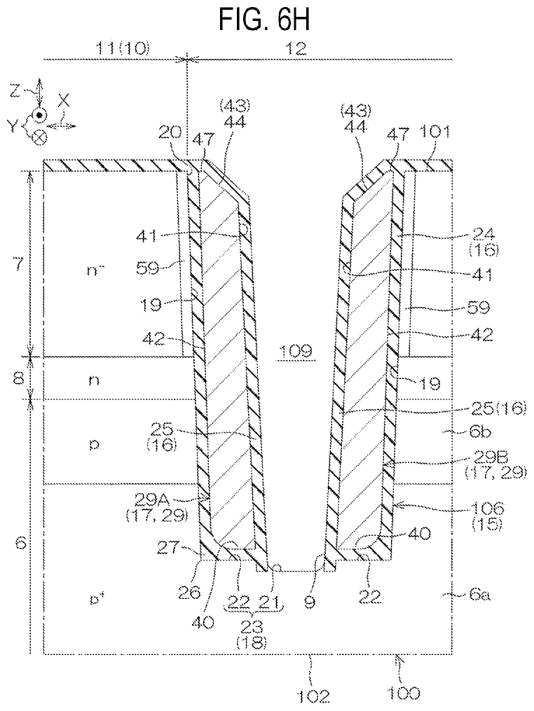

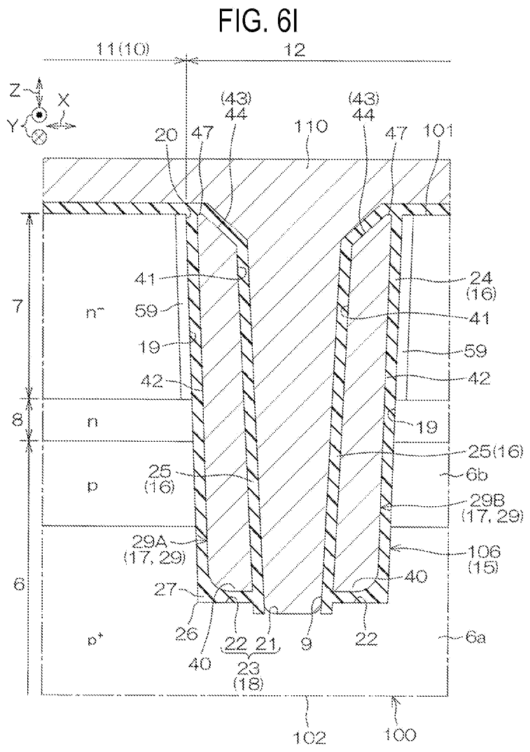

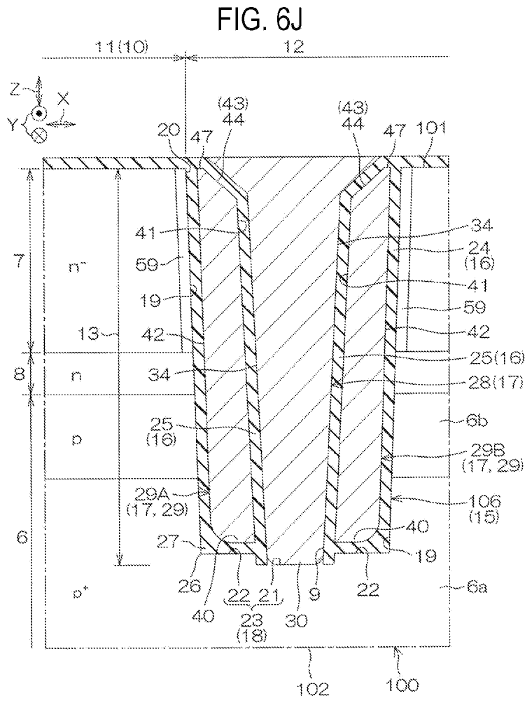

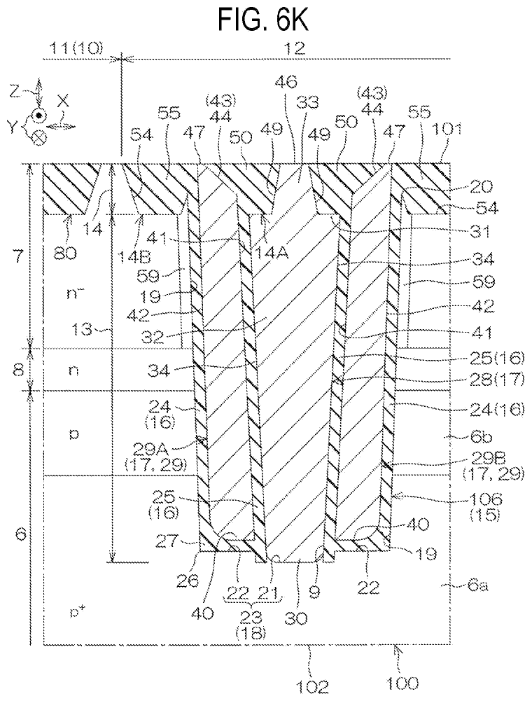

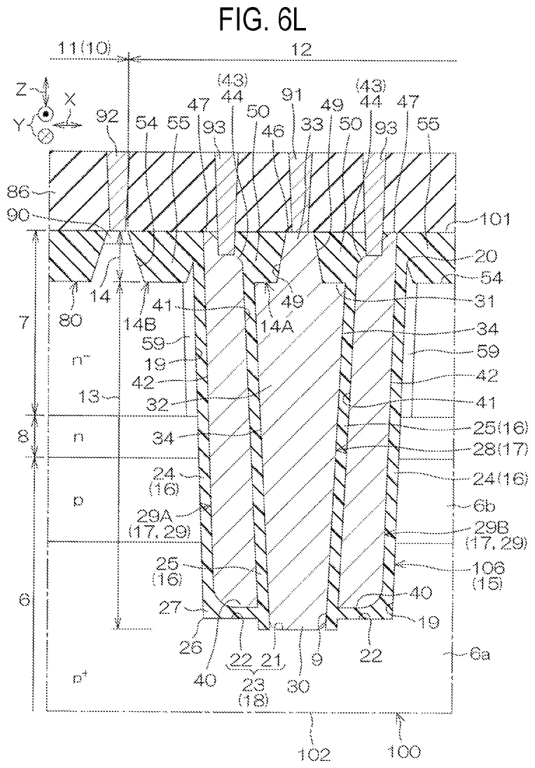

The bottom 18 of the isolation trench 15 provides an uneven surface 23 including a concave portion 21 at a central portion of the isolation trench 15 in a cross-sectional view and a pair of convex portions 22 on both sides adjacent to the central portion of the isolation trench 15. The concave portion 21 of the bottom 18 may not be formed by intentionally digging the central portion of the bottom 18 to be deeper than the convex portion 22, but for example, may be a recess caused by over-etching in an etching process (see FIG. 6G) of a first conductive material 108 and an outer insulating film 24 to be described later. A depth D₁ from a top surface of the convex portion 22 to a bottom surface of the concave portion 21 is 1/10 or less, preferably 1/300 to 1/30, of the first width W₁ of the isolation trench 15.

The isolation insulating film 16 is formed at an inner wall of the isolation trench 15. A contact opening 9 is formed over a portion of the bottom 18 of the isolation insulating film 16. The contact opening 9 exposes the first impurity region 6 within the isolation trench 15. In this embodiment, the isolation insulating film 16 is SiO₂ (silicon oxide). The isolation insulating film 16 includes the outer insulating film 24 and an inner insulating film 25.

The outer insulating film 24 is a film that insulates the semiconductor chip 2 and the isolation conductor 17 from each other and is formed at the inner wall of the isolation trench 15. The outer insulating film 24 is formed along the side wall 19 and bottom 18 of the isolation trench 15. The outer insulating film 24 has a uniform first thickness Ti at the side wall 19 and the bottom 18.

The first thickness T₁ may be an appropriate size depending on a third potential V₃ (see FIG. 3) of a second isolation conductor 29 of the isolation conductor 17, which will be described later. The first thickness T₁ may be, for example, 500 Å or more and 10,000 Å or less. The first thickness T₁ is preferably 2,000 Å or more and 5,000 Å or less. However, the outer insulating film 24 may selectively include a thick film portion 27 at a corner 26 where the side wall 19 and the bottom 18 intersect each other. As a result, a breakdown voltage of the isolation insulating film 16 at the corner 26 of the isolation trench 15 may be improved.

The isolation conductor 17 is buried at an inner side of the outer insulating film 24 in the isolation trench 15. The isolation conductor 17 is polysilicon. In this embodiment, this polysilicon is doped polysilicon added with p-type (first conductivity type) impurities (for example, boron (B)). The isolation conductor 17 may be electrically connected to the first impurity region 6 exposed from the contact opening 9.

The isolation conductor 17 includes a first isolation conductor 28 and a second isolation conductor 29 that are insulated and separated by the inner insulating film 25. The first isolation conductor 28 and the second isolation conductor 29 may be referred to as a main isolation conductor and an auxiliary isolation conductor, respectively. The first isolation conductor 28 is formed at the central portion of the isolation trench 15, and the second isolation conductors 29 are formed on both sides of the first isolation conductor 28 with the inner insulating film 25 interposed therebetween. Accordingly, the first isolation conductor 28 and the second isolation conductor 29 may be referred to as an inner isolation conductor and an outer isolation conductor, respectively.

The first isolation conductor 28 is formed to be deeper than the second isolation conductor 29 and is electrically connected to the first impurity region 6 exposed from the contact opening 9. On the other hand, the second isolation conductor 29 is covered with the outer insulating film 24 and the inner insulating film 25 and is insulated from a laminated structure of the first impurity region 6, the buried region 8, and the second impurity region 7.

Referring to FIG. 4, in this embodiment, the first isolation conductor 28 includes a lower end 30 buried in the concave portion 21 of the isolation trench 15. The first isolation conductor 28 is formed in a shape of a wall extending upward from the concave portion 21 toward the first main surface 3. Referring to FIG. 2, in this embodiment, the first isolation conductor 28 has an annular shape (in this embodiment, a quadrangular annular shape) in a plan view. More specifically, the first isolation conductor 28 has corner portions (four corners) curved in an arc-shape in a plan view.

Referring to FIG. 4, the first isolation conductor 28 integrally includes a main body portion 32 and a protrusion portion 33.

The main body portion 32 is a portion sandwiched between the inner insulating films 25 in a cross-sectional view. The main body portion 32 is formed in a tapered shape whose width increases from the lower end 30 toward an upper end 31 in a cross-sectional view. A third thickness T₃ of the first isolation conductor 28 (a thickest portion of the main body portion 32) in a lateral direction along the first main surface 3 may be, for example, 0.5 μm or more and 9 μm or less. The third thickness T₃ is preferably 1 μm or more and 2 μm or less. The main body portion 32 includes a pair of side walls 34 that provide the tapered shape of the first isolation conductor 28 in a cross-sectional view. The side walls 34 of the main body portion 32 may provide a flat or substantially flat surface from the lower end 30 to the upper end 31.

Referring to FIG. 5, the protrusion portion 33 extends from the upper end 31 of the main body portion 32 toward the first main surface 3 and is exposed from the first main surface 3. The protrusion portion 33 has a mesa-shape formed over an upper surface of the main body portion 32 in a cross-sectional view. As a result, a top side wall 35 including a side wall of the protrusion portion 33 and a top bottom wall 36 including a top wall of the main body portion 32 are formed at a top 60 of the first isolation conductor 28.

The top bottom wall 36 forms a flat surface that is bent from an upper end of the side wall 34 of the main body portion 32 and extends along the first main surface 3. In this embodiment, the top bottom wall 36 is parallel to the first main surface 3. The top bottom wall 36 has a first end 37 and a second end 38 in a direction along the first main surface 3. The first end 37 is an inner end that is relatively close to the protrusion portion 33 and forms an intersection with the top side wall 35. The second end 38 is an outer end that forms an intersection with the side wall 34 on an opposite side of the first end 37.

The top side wall 35 forms a flat surface extending upward from the first end 37 of the top bottom wall 36 toward the first main surface 3. The top side wall 35 is an inclined wall that is inclined downward from an upper end surface (a top surface 46 to be described later) of the protrusion portion 33 toward the top bottom wall 36. The top bottom wall 36 extends parallel to the first main surface 3 from a lower end 39 of the top side wall 35 toward the second isolation conductor 29.

In this embodiment, the protrusion portion 33 is formed in a tapered shape such that a width between a pair of top side walls 35 increases from the first main surface 3 toward the top bottom wall 36. As a result, wide portions of the protrusion portion 33 and the main body portion 32, both of which have a tapered shape, are integrally connected to each other. Each wide portion is a portion of the protrusion portion 33 and the main body portion 32 that has a widest width in the direction along the first main surface 3.

Referring to FIG. 4, the second isolation conductor 29 is formed in a shape of a wall that is buried from the bottom 18 of the isolation trench 15 up to a surface layer of the first main surface 3 in a space between the first isolation conductor 28 and the side wall 19 of the isolation trench 15. Referring to FIG. 2, in this embodiment, the second isolation conductor 29 has an annular shape (in this embodiment, a quadrangular annular shape) in a plan view. More specifically, the second isolation conductor 29 has corner portions (four corners) curved in an arc-shape in a plan view.

As a result, the second isolation conductor 29 is sandwiched between the first isolation conductor 28 and both the second impurity region 7 and the buried region 8 in the lateral direction along the first main surface 3. The buried region 8 is covered with the second isolation conductor 29 with the outer insulating film 24 interposed therebetween at an intermediate portion in a depth direction of the isolation trench 15.

In this embodiment, the second isolation conductors 29 include a pair of second isolation conductors 29 that are separated from each other in a cross-sectional view. The pair of second isolation conductors 29 may include an inner second isolation conductor 29A which has an annular shape in a plan view surrounded by the first isolation conductors 28 and is relatively disposed near the transistor region 11, and an outer second isolation conductor 29B which has an annular shape in a plan view surrounding the first isolation conductor 28 and is disposed opposite to the inner second isolation conductor 29A.

In this way, the pair of second isolation conductors 29 protrude from the first isolation conductor 28 on both a side toward the transistor region 11 and an opposite side thereof and are supported from below by the convex portion 22 of the bottom 18 of the isolation trench 15. Lower ends 40 of the pair of second isolation conductors 29 are disposed at the high-concentration region 6a, among the low-concentration region 6b and the high-concentration region 6a of the first impurity region 6.

The pair of second isolation conductors 29 face each other with the first isolation conductor 28 interposed therebetween. The pair of second isolation conductors 29 are formed in line symmetry to a center line C extending from a center at a width direction of the bottom 18 of the isolation trench 15 so as to have a same fourth thickness T₄. The fourth thickness T₄ of the second isolation conductor 29 in the lateral direction along the first main surface 3 may be, for example, 0.1 μm or more and 2.0 μm or less. The fourth thickness T₄ is preferably 0.2 μm or more and 1.0 μm or less. The fourth thickness T₄ of the second isolation conductor 29 may be thinner or thicker than the third thickness T₃ of the first isolation conductor 28.

In this embodiment, the pair of second isolation conductors 29 include a lower end 40 at the convex portion 22 adjacent to the lower end 30 of the first isolation conductor 28, and rise from the convex portion 22 toward the first main surface 3 along the side wall 34 of the first isolation conductor 28. As a result, the pair of second isolation conductors 29 are formed in a shape of a wall that sandwiches the first isolation conductor 28 from both inner and outer sides in the lateral direction along the first main surface 3. Therefore, the pair of second isolation conductors 29 may be referred to as a side wall that protects the entire side wall 34 of the first isolation conductor 28 from the lower end 30 to the upper end 31 from the inner and outer sides.

Each second isolation conductor 29 includes an inner wall 41 in contact with the inner insulating film 25 and an outer wall 42 opposite to the inner wall 41. The inner wall 41 of the second isolation conductor 29 may provide a flat or substantially flat surface extending along the side wall 34 of the first isolation conductor 28. The outer wall 42 of the second isolation conductor 29 may provide a flat or substantially flat surface extending along the side wall 19 of the isolation trench 15.

A top 43 of each second isolation conductor 29 includes an inclined wall 44. The inclined wall 44 connects the outer wall 42 and the inner wall 41 of the second isolation conductor 29. The inclined wall 44 is inclined downward from the outer wall 42 toward the inner wall 41. In this embodiment, the inclined wall 44 is formed continuously over an entire circumferential direction of each second isolation conductor 29. Therefore, a bank-shaped inclined wall 44 is formed on the annular top 43 of each second isolation conductor 29 in a plan view so that a top of the isolation conductor 17 is recessed toward the first isolation conductor 28.

Referring to FIG. 5, the inclined wall 44 of each second isolation conductor 29 includes a lower end 45 adjacent to the second end 38 of the top bottom wall 36 of the first isolation conductor 28 with the inner insulating film 25 interposed therebetween. In this embodiment, the top 43 of each second isolation conductor 29 has the inclined wall 44 that is bent directly from an upper end of the inner wall 41 that faces the side wall 34 of the first isolation conductor 28 with the inner insulating film 25 interposed therebetween. The lower end 45 of the inclined wall 44 is an intersection between the inclined wall 44 and the inner wall 41. For example, the lower end 45 of the inclined wall 44 may be located at a position that provides an inclined extension line L (imaginary line) that extends downward from the lower end 45 and intersects the top bottom wall 36 of the first isolation conductor 28 in a cross-sectional view.

Referring to FIG. 4, the inner insulating film 25 is a film that insulates the first isolation conductor 28 and the second isolation conductor 29 from each other, and is formed between the first isolation conductor 28 and the second isolation conductor 29. The inner insulating film 25 covers the side wall 34 of the first isolation conductor 28 with a uniform second thickness T₂.

The second thickness T₂ may be an appropriate size depending on a first potential V₁ (see FIG. 3) of the first isolation conductor 28 and the third potential V₃ (see FIG. 3) of the second isolation conductor 29, which will be described later. The second thickness T₂ may be the same as or different from the first thickness T₁. The second thickness T₂ may be, for example, 500 Å or more and 10,000 Å or less. The second thickness T₂ is preferably 2,000 Å or more and 5,000 Å or less.

A contact opening 9 is formed over a portion at the bottom 18 of the inner insulating film 25. The contact opening 9 exposes the first impurity region 6 within the isolation trench 15.

A plurality of second trench structures 14 are formed. The plurality of second trench structures 14 may be referred to as STI (Shallow Trench Isolation) structures. The plurality of second trench structures 14 cover the outer insulating film 24 and the inner insulating film 25 and are formed at intervals from each other so as to expose the top surface 46 (first top surface) of the first isolation conductor 28 and a top surface 47 (second top surface) of the second isolation conductor 29.

The plurality of second trench structures 14 are formed at a distance from the buried region 8 toward the first main surface 3. That is, the plurality of second trench structures 14 are formed within a thickness range of the second impurity region 7. The second trench structure 14 extends along the first trench structure 13 in a plan view. Referring to FIG. 2, in this embodiment, the second trench structure 14 is formed in an annular shape (in this embodiment, a quadrangular annular shape) extending along the first trench structure 13 in a plan view.

Referring to FIGS. 2 and 5, the second trench structure 14 includes an inner trench structure 14A and an outer trench structure 14B. Referring to FIG. 2, the inner trench structure 14A crosses a boundary 48 between the first isolation conductor 28 and the second isolation conductor 29 inside the isolation trench 15 and is formed in an annular shape along the boundary 48 so as to cover the annular boundary 48 in a plan view. The outer trench structure 14B is separated from the second isolation conductor 29 outside the isolation trench 15 and is formed in an annular shape along the isolation trench 15. The outer trench structure 14B may include a trench structure surrounded by the isolation trench 15 and a trench structure surrounding the isolation trench 15.

Referring to FIG. 5, the inner trench structure 14A includes a shallow trench 49 as an example of a second isolation trench, and a buried insulator 50.

The shallow trench 49 is a space defined by the top side wall 35 and the top bottom wall 36 of the first isolation conductor 28 and the inclined wall 44 of the second isolation conductor 29. For example, when comparing a first inclination angle θ₁ of the top side wall 35 with respect to the top bottom wall 36 and a second inclination angle θ₂ of the inclined wall 44 with respect to the top bottom wall 36, the second inclination angle θ₂ is larger than the first inclination angle θ₁. Therefore, the shallow trench 49 may include a bottom surface 51 (the top bottom wall 36) along the first main surface 3, and a second side surface 53 (the inclined wall 44) and a first side surface 52 (the top side wall 35) that extend from the bottom surface 51 toward the side wall 19 of the isolation trench 15 and an opposite side thereof, respectively, and have different inclination degrees.

The buried insulator 50 is buried in the shallow trench 49. The buried insulator 50 is formed integrally with the inner insulating film 25. The buried insulator 50 may include at least one selected from the group of an oxide film such as silicon oxide and a nitride film such as silicon nitride.

Referring to FIG. 5, the outer trench structure 14B includes a shallow trench 54 and a buried insulator 55.

The shallow trench 54 may have a bottom surface 56 along the first main surface 3, and a first side surface 57 and a second side surface 58 that extend from the bottom surface 56 toward the side wall 19 of the isolation trench 15 and an opposite side thereof, respectively, and have a same inclination degree.

The buried insulator 55 is buried in the shallow trench 54. The buried insulator 55 is formed integrally with the outer insulating film 24. The buried insulator 55 may include at least one selected from the group of an oxide film such as silicon oxide and a nitride film such as silicon nitride.

Referring to FIGS. 4 and 5, the semiconductor chip 2 further includes an n-type sinker region 59. The sinker region 59 has a higher n-type impurity concentration than the second impurity region 7. For example, the n-type impurity concentration of the sinker region 59 may be 1×10¹⁷ cm⁻³ or more and 1×10²² cm⁻³ or less. The sinker region 59 is formed along the side wall 19 of the isolation trench 15 in a vicinity of an interface with the second isolation conductor 29 in the second impurity region 7.

Referring to FIG. 3, the semiconductor device 1A includes a planar gate type MISFET cell 70 as an example of a functional device formed in the transistor region 11. In FIG. 2, illustration of the MISFET cell 70 is omitted. Depending on a magnitude of a drain-source voltage of the MISFET cell 70, the MISFET cell 70 may take the form of one of a HV (High Voltage)-MISFET cell (for example, 100 V or more and 1,000 V or less), a MV (Middle Voltage)-MISFET cell (for example, 30 V or more and 100 V or less), and a LV (Low Voltage)-MISFET cell (for example, 1 V or more and 30 V or less). In this embodiment, an example will be described in which the MISFET cell 70 is the HV-MISFET cell, but this is not intended to limit the form of the MISFET cell 70 to the HV-MISFET cell.

In a cross-sectional view, the MISFET cell 70 includes at least one (in this embodiment, one) n-type first well region 71, at least one (in this embodiment, a plurality of) p-type second well region 72, at least one (in this embodiment, one) n-type drain region 73, at least one (in this embodiment, a plurality of) n-type source region 74, at least one (in this embodiment, a plurality of) p-type channel region 75, at least one (in this embodiment, a plurality of) p-type contact region 76, and at least one (in this embodiment, a plurality of) planar gate structure 77.

The first well region 71 is formed at a surface layer of the second impurity region 7 in the transistor region 11. The first well region 71 has a higher n-type impurity concentration than the second impurity region 7. The plurality of second well regions 72 are formed at the surface layer of the second impurity region 7 at intervals from the first well region 71 in the transistor region 11. One second well region 72 is formed at an interval from the first well region 71 on one side in the first direction X, and the other second well region 72 is formed at an interval from the first well region 71 on the other side in the first direction X.

The drain region 73 is formed at a surface layer of the first well region 71 at an interval inward from a periphery of the first well region 71. The plurality of source regions 74 are respectively formed at surface layers of the corresponding second well regions 72 at intervals inward from peripheries of the corresponding second well regions 72. The plurality of channel regions 75 are respectively formed between the second impurity region 7 and the source regions 74 at the surface layers of the corresponding second well regions 72. The plurality of contact regions 76 are respectively formed at the surface layers of the corresponding second well regions 72 at intervals inward from the peripheries of the corresponding second well regions 72. The plurality of contact regions 76 are adjacent to the corresponding source regions 74.

The plurality of planar gate structures 77 are respectively formed over the first main surface 3 so as to cover the corresponding channel regions 75, and control on/off states of the corresponding channel regions 75. In this embodiment, the plurality of planar gate structures 77 are respectively formed so as to extend over the first well region 71 and the corresponding source regions 74.

The plurality of planar gate structures 77 include a gate insulating film 78 and a gate electrode 79 laminated in this order from the first main surface 3. The gate insulating film 78 may include silicon oxide (SiO₂) or may include a tetraethyl orthosilicate (TEOS) film. Preferably, the gate insulating film 78 includes a silicon oxide film made of oxide of the semiconductor chip 2. Preferably, the gate electrode 79 includes polysilicon. The gate electrode 79 may include one or both of an n-type region and a p-type region formed in polysilicon.

Referring to FIG. 3, the semiconductor device 1A includes a plurality of third trench structures 80 formed at the first main surface 3. The plurality of third trench structures 80 may also be referred to as STI structures. In this embodiment, the plurality of third trench structures 80 are formed at intervals from each other so as to partition the drain region 73 from other regions and to partition outer edges of the plurality of second well regions 72 from other regions.

In this embodiment, the plurality of third trench structures 80 are formed at a distance from the buried region 8 toward the first main surface 3. That is, the plurality of third trench structures 80 are formed within the thickness range of the second impurity region 7.

Each of the third trench structures 80 includes a shallow trench 81 and a buried insulator 82. The shallow trench 81 is dug down from the first main surface 3 toward the second main surface 4. The buried insulator 82 is buried in the shallow trench 81. The buried insulator 82 may include at least one selected from the group of silicon oxide and silicon nitride.

An interlayer insulating layer 86 is formed at the first main surface 3 of the semiconductor chip 2. In this embodiment, the interlayer insulating layer 86 is formed of a single insulating layer. The interlayer insulating layer 86 may include, for example, silicon oxide (SiO₂). A drain contact electrode 83, a source contact electrode 84, a gate contact electrode 85, a first contact electrode 91, a back gate contact electrode 92, and a second contact electrode 93 are buried in the interlayer insulating layer 86. The drain contact electrode 83, the source contact electrode 84, the gate contact electrode 85, the first contact electrode 91, the back gate contact electrode 92, and the second contact electrode 93 may also be referred to as a drain via, a source via, a gate via, a first via, a back gate via, and a second via, respectively. The drain contact electrode 83, the source contact electrode 84, the gate contact electrode 85, the first contact electrode 91, the back gate contact electrode 92, and the second contact electrode 93 may each be formed of tungsten (W).

In the transistor region 11, a drain potential V_{D} is applied to the drain region 73 via the drain contact electrode 83. The drain potential V_{D} is a positive device potential in the transistor region 11. A source potential V_{S} lower than the drain potential V_{D} is applied to the source region 74 via the source contact electrode 84. A gate potential V_{G} is applied to the gate electrode 79 via the gate contact electrode 85.

The first potential V₁ is applied to the first isolation conductor 28 via the first contact electrode 91. The first potential V₁ applied to the first isolation conductor 28 is applied to the high-concentration region 6a via the first isolation conductor 28. As a result, the high-concentration region 6a is fixed at a same potential as the first isolation conductor 28. The first potential V₁ is preferably a potential equal to or lower than the drain potential V_{D} (preferably lower than the drain potential V_{D}). That is, the first potential V₁ is preferably lower than a maximum device potential. The first potential V₁ may be a reference potential serving as a reference for circuit operation or a ground potential. The first potential V₁ is preferably the ground potential.

A second potential V₂ is applied to a back gate contact region 90, which is formed between the first trench structure 13 and the transistor region 11 in the semiconductor chip 2, via the back gate contact electrode 92. The second potential V₂ is preferably a potential equal to or lower than the drain potential V_{D} (preferably lower than the drain potential V_{D}). The second potential V₂ is preferably lower than the maximum device potential. The second potential V₂ may be equal to or higher than the first potential V₁ (V₁≤V₂). The second potential V₂ may exceed the first potential V₁ (V₁<V₂). The second potential V₂ may be a reference potential or a ground potential.

The third potential V₃ is applied to the second isolation conductor 29 via the second contact electrode 93. The third potential V₃ is preferably an intermediate potential between the first potential V₁ and the second potential V₂ (V₁<V₃<V₂). When the third potential V₃ is the intermediate potential between the first potential V₁ and the second potential V₂, a voltage decreases stepwise from the second potential V₂ toward the first potential V₁, such that an electric field may be relaxed stepwise in the lateral direction along the first main surface 3.

Referring to FIG. 2, the first contact electrode 91 and the second contact electrode 93 may be arranged in a pattern close to each other. For example, in a plan view, the isolation trench 15 includes a first region 94 in which a plurality of first contact electrodes 91 are arranged in a concentrated manner, and a second region 95 separated from the first region 94 in a longitudinal direction (in this embodiment, a circumferential direction) of the isolation trench 15. The first contact electrode 91 and the second contact electrode 93 are arranged in both the first region 94 and the second region 95 and are adjacent to each other in the width direction of the isolation trench 15 in each of the regions 94 and 95.

In this embodiment, the plurality of first contact electrodes 91 are arranged at intervals along the longitudinal direction of the isolation trench 15 in each of the first region 94 and the second region 95. Further, a plurality of second contact electrodes 93 are arranged at intervals along the longitudinal direction of the isolation trench 15 in each of the first region 94 and the second region 95.

Referring to FIG. 5, the first contact electrode 91 penetrates the interlayer insulating layer 86 and is connected to the top 60 of the first isolation conductor 28. In this embodiment, the first contact electrode 91 is connected to the top surface 46 of the protrusion portion 33. The first contact electrode 91 has a first electrode width W_{E1} in the lateral direction along the first main surface 3. The first electrode width W_{E1} may be, for example, 0.1 μm or more and 1 μm or less.

Referring to FIG. 5, the second contact electrode 93 penetrates the interlayer insulating layer 86 and a portion of the buried insulator 50 and is connected to the top 43 of the second isolation conductor 29. In this embodiment, the second contact electrode 93 is connected to the inclined wall 44 of the second isolation conductor 29. The second contact electrode 93 may have a buried portion 96 (in this embodiment, a lower end 97) buried in the top 43 of the second isolation conductor 29 via the inclined wall 44. A recessed concave portion 98 may be selectively formed at the top 43 of the second isolation conductor 29, and the buried portion 96 of the second isolation conductor 29 may be disposed in the concave portion 98.

The second contact electrode 93 has a second electrode width W_{E2} in the lateral direction along the first main surface 3. The second electrode width W_{E2} may be wider than the first electrode width WE1 and may be, for example, 0.1 μm or more and 1 μm or less.

FIGS. 6A to 6L, which are views corresponding to FIG. 4, show parts of a process of manufacturing the semiconductor device 1A according to the first embodiment of the present disclosure.

Referring to FIG. 6A, in order to manufacture the semiconductor device 1A, a semiconductor wafer 100 that becomes a base of the semiconductor chip 2 is prepared. The semiconductor wafer 100 has a first wafer main surface 101 corresponding to the first main surface 3 and a second wafer main surface 102 corresponding to the second main surface 4. Although an outline of the second wafer main surface 102 is not shown in the enlarged view of FIG. 6A, for the sake of convenience of explanation, a place of the semiconductor wafer 100 closest to the second wafer main surface 102 is shown as the second wafer main surface 102.

The semiconductor wafer 100 includes the first impurity region 6, the second impurity region 7, and the buried region 8. The first impurity region 6 includes the high-concentration region 6a and the low-concentration region 6b. The high-concentration region 6a includes a p-type semiconductor substrate. The low-concentration region 6b includes a p-type epitaxial layer, which is laminated on the semiconductor substrate, by an epitaxial growth method.

Next, a mask 103 is formed over the entire first wafer main surface 101 of the semiconductor wafer 100. The mask 103 may be a hard mask made of, for example, silicon oxide (SiO₂). The mask 103 is formed by, for example, a thermal oxidation method or a CVD method.

Next, referring to FIG. 6B, a resist 104 is formed over the mask 103. The resist 104 has an opening 105 having a shape corresponding to the isolation trench 15. By selectively etching the mask 103 through the opening 105, the opening 105 penetrates the mask 103 to reach the first wafer main surface 101.

Next, referring to FIG. 6C, the semiconductor wafer 100 is selectively etched through the opening 105 of the mask 103. As a result, an annular first trench 106 is formed at the first wafer main surface 101 to partition the transistor region 11 (the device region 10). The first trench 106 penetrates the second impurity region 7 and the buried region 8 to expose the low-concentration region 6b. The first trench 106 is formed in a tapered shape whose width increases from the bottom 18 toward the first wafer main surface 101 in a cross-sectional view. The etching method may be a dry etching method or a wet etching method.

The first trench 106 has a shape that becomes a base of the isolation trench 15, and has the side wall 19 and the bottom 18. At this stage, the uneven surface 23 is not formed at the bottom 18, but a flat surface is formed at the bottom 18.

Next, referring to FIG. 6D, an n-type impurity is implanted into an inner wall of the first trench 106. The n-type impurity is implanted obliquely at a certain angle with respect to the first wafer main surface 101. As a result, the sinker region 59 having a higher concentration than the second impurity region 7 is formed. The sinker region 59 is formed with the mask 103 remaining over the first wafer main surface 101. This may prevent an entire surface layer of the first wafer main surface 101 from being transformed into an n-type impurity region having a same concentration as the sinker region 59.

Next, referring to FIG. 6E, the outer insulating film 24 is formed at the inner wall of the first trench 106 and the first wafer main surface 101. The outer insulating film 24 is formed by, for example, a thermal oxidation method or a CVD method. The outer insulating film 24 is not a film that backfills the first trench 106, but is formed in the form of an integral layer along the inner wall of the first trench 106 and the first wafer main surface 101. As a result, a recess 107, which is a space defined by the outer insulating film 24, is formed within the first trench 106.

Next, referring to FIG. 6F, the first conductive material 108 that becomes a base of the second isolation conductor 29 is deposited on the first wafer main surface 101. In this embodiment, the first conductive material 108 includes doped polysilicon added with p-type (first conductivity type) impurities. The first conductive material 108 is formed in the form of a layer on the outer insulating film 24 within the recess 107 so as to leave the recess 107 within the first trench 106. The first conductive material 108 may be deposited by a CVD method.

Next, referring to FIG. 6G, unnecessary portions of the first conductive material 108 and unnecessary portions of the outer insulating film 24 are removed. In this embodiment, a portion of the first conductive material 108 on the bottom 18 of the first trench 106 and a portion of the outer insulating film 24 on the bottom 18 of the first trench 106 are removed by selective etching. As a result, the second isolation conductor 29 (the outer isolation conductor) made of the first conductive material 108 remaining on the side wall 19 of the first trench 106 is formed. Further, the contact opening 9 is formed by removing the outer insulating film 24.

At this time, in order to ensure contact between the first impurity region 6 and the first isolation conductor 28, care must be taken so that the outer insulating film 24 does not remain on the bottom 18. As a result, etching time for forming the contact opening 9 is lengthened, and the central portion of the bottom 18 of the first trench 106 is selectively over-etched. As a result, the concave portion 21 is formed at the bottom 18, and the bottom 18 becomes the uneven surface 23. Further, a second trench 109 partitioned by the second isolation conductor 29 is formed within the first trench 106. The second trench 109 is formed by the recess 107.

Further, in this step, at the surface layer of the first wafer main surface 101, the first conductive material 108 on the first wafer main surface 101 is etched, and then an upper portion of the first conductive material 108 on the side wall 19 of the first trench 106 is selectively etched. As a result, the inclined wall 44 is formed at the top 43 of the second isolation conductor 29.

Next, referring to FIG. 6H, the inner insulating film 25 is formed at the inner wall of the second trench 109. The inner insulating film 25 may be formed, for example, by thermal oxidation of the first impurity region 6 and the second isolation conductor 29 exposed as inner walls of the second trench 109.

Next, referring to FIG. 6I, a second conductive material 110 that becomes a base of the first isolation conductor 28 is deposited on the first wafer main surface 101. In this embodiment, the second conductive material 110 includes doped polysilicon added with p-type (first conductivity type) impurities. The deposition of the second conductive material 110 continues until an inner space of the inner insulating film 25 of the second trench 109 is filled. The second conductive material 110 may be deposited by a CVD method.

Next, referring to FIG. 6J, unnecessary portions of the deposited second conductive material 110 are removed. This step includes a step of removing the second conductive material 110 by a grinding method until the outer insulating film 24 on the first wafer main surface 101 is exposed. The grinding method may be a CMP (Chemical Mechanical Polishing) method. As a result, the first isolation conductor 28 is formed by the second conductive material 110 remaining within the second trench 109. Accordingly, the first trench structure 13 is formed. Of course, in this step, an etching method (wet etching method or dry etching method) may be used instead of the grinding method, or the grinding method and the etching method may be combined. After forming the first isolation conductor 28, the outer insulating film 24 remaining on the first wafer main surface 101 is removed.

Next, referring to FIG. 6K, the shallow trench 49 and the shallow trench 54 are formed, and the buried insulator 50 and the buried insulator 55 are buried in the shallow trench 49 and the shallow trench 54, respectively. The protrusion portion 33 of the first isolation conductor 28 is formed by partially removing the top of the first isolation conductor 28 by etching when forming the shallow trench 49.

On the other hand, since the top 43 of the second isolation conductor 29 is covered with the inner insulating film 25 as shown in FIG. 6J, contact of the top 43 with an etching gas (or etching solution) is prevented. Accordingly, the top 43 of the second isolation conductor 29 is protected during the formation of the shallow trench 49, and the shape of the inclined wall 44 is maintained. As a result, a cross-sectional shape of the shallow trench 49 becomes asymmetrical (see FIG. 5). Specifically, the first side surface 52 and the second side surface 53 of the shallow trench 49 are formed such that the second inclination angle θ₂ is larger than the first inclination angle θ₁.

Next, a functional device such as the MISFET cell 70 is formed at the first wafer main surface 101 of the semiconductor wafer 100. Next, referring to FIG. 6L, the interlayer insulating layer 86 is formed at the first wafer main surface 101, and via electrodes such as the first contact electrode 91 and the second contact electrode 93 are formed in the interlayer insulating layer 86. Thereafter, the semiconductor wafer 100 is divided into a plurality of semiconductor devices 1A through a process of forming elements necessary for the semiconductor device 1A. As a result, chips of the semiconductor devices 1A are obtained.

As described above, according to the semiconductor device 1A, the isolation conductor 17 of the first trench structure 13 has the second isolation conductor 29 in addition to the first isolation conductor 28. The second isolation conductor 29 is sandwiched between the buried region 8 and the first isolation conductor 28 in the lateral direction along the first main surface 3.

The buried region 8 covered with the second isolation conductor 29 is sandwiched between the p-type first impurity region 6 and the low-concentration n-type second impurity region 7, and it is thus easier for an electric field to concentrate on the buried region 8 than on the bottom 18 of the isolation trench 15. This is because an equipotential line is bent into an L-shape in a cross-section at a boundary between the first isolation conductor 28 (having the same potential as the first impurity region 6), which is connected to the p-type first impurity region 6 and extends in the normal direction of the first main surface 3, and the n-type second impurity region 7 and the buried region 8, which are formed along the first main surface 3 and intersect the first isolation conductor 28. The electric field tends to concentrate at a corner of the L-shaped portion of the equipotential line. Therefore, if electric field concentration occurs at the side wall 19 of the isolation trench 15 at a portion between the buried region 8 and the isolation conductor 17, a breakdown voltage of the semiconductor device 1A may decrease.

Therefore, by providing the second isolation conductor 29 covering the buried region 8, it is possible to prevent at least the inner insulating film 25 from being destroyed even if the electric field is concentrated. As a result, the breakdown voltage in the lateral direction along the first main surface 3 of the semiconductor chip 2 may be improved.

Further, the second isolation conductor 29 is formed from the bottom 18 of the isolation trench 15 to the top 20 thereof and covers the top 20. Since the top 20 of the isolation trench 15 has a corner at which the first main surface 3 and the side wall 19 intersect, the electric field tends to concentrate thereon. Since this top 20 is also covered with the second isolation conductor 29, a breakdown voltage of the isolation insulating film 16 at the top 20 of the isolation trench 15 may also be improved.

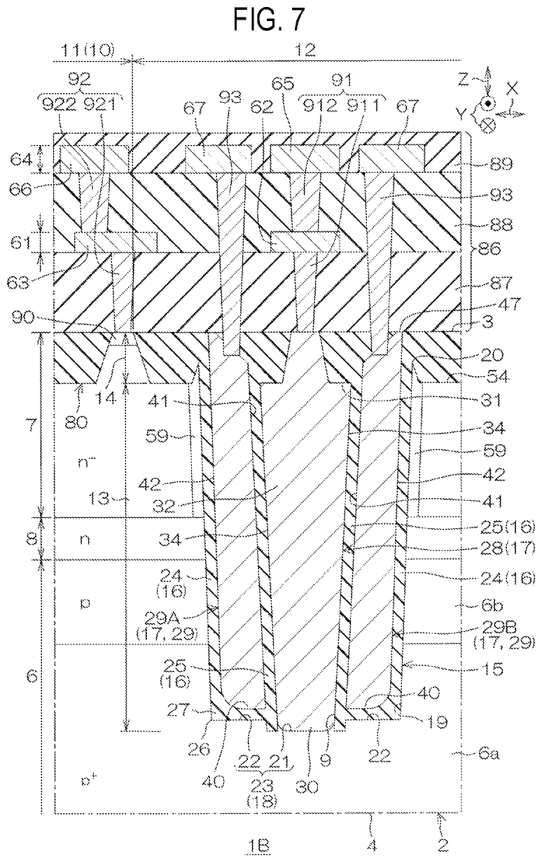

FIG. 7 is an enlarged cross-sectional view of a main part of a semiconductor device 1B according to a second embodiment of the present disclosure. In the following, structures corresponding to those described in FIG. 4 are denoted by the same reference numerals, and explanation thereof will not be repeated.

In the semiconductor device 1B, the interlayer insulating layer 86 may be a multilayer film having a laminated structure of a plurality of interlayer insulating layers. In this embodiment, the interlayer insulating layer 86 includes a first interlayer insulating layer 87, a second interlayer insulating layer 88 above the first interlayer insulating layer 87, and a third interlayer insulating layer 89 above the second interlayer insulating layer 88.

A first wiring layer 61 is formed over the first interlayer insulating layer 87. The first wiring layer 61 is formed of metal including, for example, aluminum (Al). The first wiring layer 61 is covered with the second interlayer insulating layer 88. The first wiring layer 61 is separated into a plurality of independent wirings. In this embodiment, the first wiring layer 61 includes a first contact lower layer wiring 62 and a back gate lower layer wiring 63.

A second wiring layer 64 is formed over the second interlayer insulating layer 88. The second wiring layer 64 is formed of metal including, for example, aluminum (Al). The second wiring layer 64 is covered with the third interlayer insulating layer 89. The second wiring layer 64 is separated into a plurality of independent wirings. In this embodiment, the second wiring layer 64 includes a first contact upper layer wiring 65, a back gate upper layer wiring 66, and a second contact wiring 67.

The first contact electrode 91 is separated into a lower via electrode 911 buried in the first interlayer insulating layer 87 and an upper via electrode 912 buried in the second interlayer insulating layer 88 with the first contact lower layer wiring 62 interposed therebetween. The lower via electrode 911 connects the first contact lower layer wiring 62 and the first isolation conductor 28. The upper via electrode 912 connects the first contact upper layer wiring 65 and the first contact lower layer wiring 62.

The back gate contact electrode 92 is separated into a lower via electrode 921 buried in the first interlayer insulating layer 87 and an upper via electrode 922 buried in the second interlayer insulating layer 88 with the back gate lower layer wiring 63 interposed therebetween. The lower via electrode 921 connects the back gate lower layer wiring 63 and the back gate contact region 90. The upper via electrode 922 connects the back gate upper layer wiring 66 and the back gate lower layer wiring 63.

The second contact electrode 93 is buried continuously through the second interlayer insulating layer 88 and the first interlayer insulating layer 87. The second contact electrode 93 has an integrated structure including a portion buried in the first interlayer insulating layer 87 and a portion buried in the second interlayer insulating layer 88, without being separated at a boundary between the first interlayer insulating layer 87 and the second interlayer insulating layer 88. Therefore, the second contact electrode 93 may be referred to as a long via electrode that is longer than the lower via electrode 911 and the upper via electrode 912 of the first contact electrode 91.

As described above, according to this semiconductor device 1B, the isolation conductor 17 of the first trench structure 13 has the second isolation conductor 29 in addition to the first isolation conductor 28. Therefore, similarly to the semiconductor device 1A, a breakdown voltage in the lateral direction along the first main surface 3 of the semiconductor chip 2 may be improved.

Although the embodiments of the present disclosure have been described, the present disclosure may be implemented in other forms.

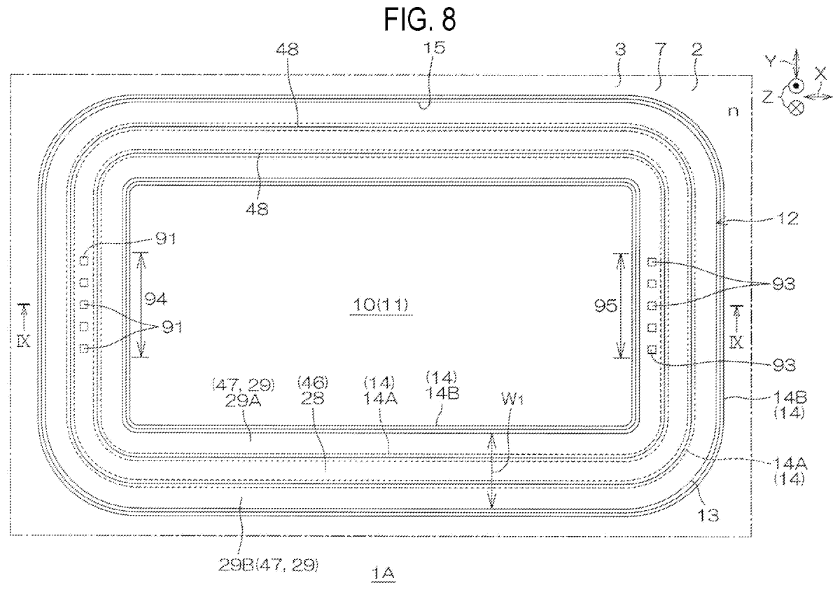

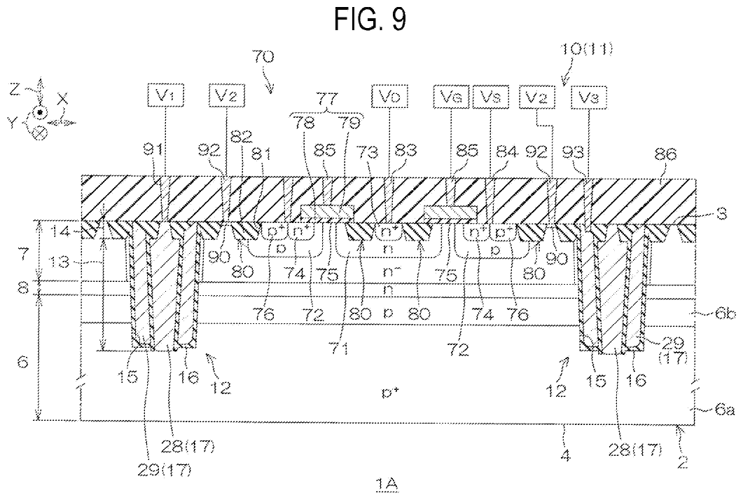

For example, referring to FIGS. 8 and 9, the first contact electrode 91 and the second contact electrode 93 do not need to be arranged at the same location in the circumferential direction of the isolation trench 15. For example, the plurality of first contact electrodes 91 may be arranged in a concentrated manner in the first region 94, and the second contact electrodes 93 may not be arranged in the first region 94. On the other hand, the plurality of second contact electrodes 93 may be arranged in a concentrated manner in the second region 95, and the first contact electrode 91 may not be arranged in the second region 95.

Further, referring to FIGS. 8 and 9, the second contact electrode 93 does not need to be connected to both of the pair of second isolation conductors 29, but may be selectively connected to either one of the second isolation conductors 29. For example, it is preferable to selectively connect the second contact electrode 93 to the inner second isolation conductor 29A, which is relatively located closer to the transistor region 11, of the pair of second isolation conductors 29A and 29B. As a result, a voltage may be lowered stepwise from the second potential V₂ toward the first potential V₁, and an effect of relaxing the electric field stepwise in the lateral direction along the first main surface 3 may be obtained.

As an example, in the above-described embodiments, the buried region 8 has been shown as an example of an electric field concentration portion in the semiconductor chip 2, but a target for improving the breakdown voltage by covering the second isolation conductor 29 is not limited to the buried region 8. For example, the target may be the top 20 of the isolation trench 15.

As an example, although the element isolation portion 12 has been described as one that annularly surrounds one transistor region 11 and isolates it from another device region 10, it may also define a boundary between two adjacent transistor regions 11.

As an example, a configuration may be adopted in which the conductivity type of each semiconductor portion of the semiconductor devices 1A and 1B is reversed. For example, in the semiconductor devices 1A and 1B, the p-type (first conductivity type) portion may be n-type, and the n-type (second conductivity type) portion may be p-type.

As described above, the embodiments of the present disclosure are illustrative in all respects and should not be construed as limiting, and are intended to include changes in all respects.

The features described below may be extracted from the description of the present disclosure and the drawings.

### Supplementary Note 1-1

A semiconductor device (1A, 1B) including:
a semiconductor chip (2) including a first main surface (3) and a second main surface (4) opposite to the first main surface (3); and
an element isolation portion (12) formed at the first main surface (3) of the semiconductor chip (2) and partitioning a device region (10, 11),
wherein the element isolation portion (12) includes:
   a first isolation trench (15) formed at the first main surface (3) of the semiconductor chip (2);
   an isolation insulating film (16) formed at an inner wall (19, 18) of the first isolation trench (15); and
   an isolation conductor (17) buried in the first isolation trench (15) via the isolation insulating film (16),
wherein the isolation conductor (17) includes:
   a first isolation conductor (28) formed at a central portion of the first isolation trench (15); and
   at least one second isolation conductor (29) formed at a side of the first isolation conductor (28) with an inner insulating film (25), which is a portion of the isolation insulating film (16), interposed between the first isolation conductor (28) and the at least one second isolation conductor (29),
wherein the at least one second isolation conductor (29) includes an inner wall (41) in contact with the inner insulating film (25) and an outer wall (42) opposite to the inner wall (41), and
wherein a top (43) of the at least one second isolation conductor includes an inclined wall (44) that connects the outer wall (42) to the inner wall (41) and is inclined downward from the outer wall (42) toward the inner wall (41).

According to this configuration, the isolation conductor (17) includes the second isolation conductor (29) in addition to the first isolation conductor (28). Accordingly, even if an electric field is concentrated in the lateral direction along the first main surface (3), it is possible to prevent at least the inner insulating film (25) from being destroyed. As a result, it is possible to improve a breakdown voltage in the lateral direction along the first main surface (3) of the semiconductor chip (2).

### Supplementary Note 1-2

The semiconductor device (1A, 1B) of Supplementary Note 1-1, further including: at a surface layer of the first main surface (3) of the semiconductor chip (2),
a second isolation trench (49) formed to cross a boundary between the first isolation conductor (28) and the at least one second isolation conductor (29) along the first main surface (3); and
a buried insulator (50) buried in the second isolation trench (49),
wherein the first isolation conductor (28) includes a top side wall (35) facing the inclined wall (44) of the at least one second isolation conductor (29) in a direction along the first main surface (3), and a top bottom wall (36) extending from a lower end (39) of the top side wall (35) toward the at least one second isolation conductor (29).

### Supplementary Note 1-3

The semiconductor device (1A, 1B) of Supplementary Note 1-2, wherein the inclined wall (44) of the at least one second isolation conductor (29) includes a lower end (45) adjacent to an end (38) of the top bottom wall (36) of the first isolation conductor (28) with the inner insulating film (25) interposed between the first isolation conductor (28) and the at least one second isolation conductor (29).

### Supplementary Note 1-4

The semiconductor device (1A, 1B) of any one of Supplementary Notes 1-1 to 1-3, wherein the least one second isolation conductor (29) includes a pair of second isolation conductors (29A, 29B),
wherein the isolation conductor (17) includes the pair of second isolation conductors (29A, 29B) separated from each other in a cross-sectional view, and
wherein the pair of second isolation conductors (29A, 29B) sandwich the first isolation conductor (28) in a lateral direction along the first main surface (3), and the pair of second isolation conductors (29A, 29B) is a pair of side walls (29A, 29B) that cover the first isolation conductor (28) from a lower end (30) of the first isolation conductor (28) to a top (60) of the first isolation conductor (28).

### Supplementary Note 1-5

The semiconductor device (1A, 1B) of Supplementary Note 1-4, wherein a bottom (18) of the first isolation trench (15) includes an uneven surface (23) including a concave portion (21) at the central portion and a pair of convex portions (22) at both sides adjacent to the central portion,
wherein the lower end (30) of the first isolation conductor (28) is buried in the concave portion (21), and
wherein the pair of side walls (29A, 29B) are supported by the pair of convex portions (22).

### Supplementary Note 1-6

The semiconductor device (1A, 1B) of Supplementary Note 1-5, wherein a depth (D₁) from a top surface of the convex portions (22) to a bottom surface of the concave portion (21) is 1/10 or less of a width (W₁) of the first isolation trench (15).

### Supplementary Note 1-7

The semiconductor device (1A, 1B) of any one of Supplementary Notes 1-1 to 1-6, further including:
an interlayer insulating layer (86) formed over the first main surface (3) of the semiconductor chip (2);
at least one first via electrode (91) buried in the interlayer insulating layer (86) and connected to a top (60) of the first isolation conductor (28); and
at least one second via electrode (93) buried in the interlayer insulating layer (86) and connected to the top (43) of the at least one second isolation conductor (29),
wherein a second width (W_{E2}) of the at least one second via electrode (93) is wider than a first width (W_{E1}) of the at least one first via electrode (91).

### Supplementary Note 1-8

The semiconductor device (1B) of Supplementary Note 1-7, wherein the interlayer insulating layer (86) includes a first interlayer insulating layer (87) and a second interlayer insulating layer (88) formed over the first interlayer insulating layer (87) and further includes a first wiring layer (61, 62) formed between the first interlayer insulating layer (87) and the second interlayer insulating layer (88),
wherein the at least one first via electrode (91) is separated into a lower via electrode (911) buried in the first interlayer insulating layer (87) and an upper via electrode (912) buried in the second interlayer insulating layer (88), with the first wiring layer (61, 62) interposed between the lower via electrode (911) and the upper via electrode (912), and
wherein the at least one second via electrode (93) includes a long via electrode that is buried through the second interlayer insulating layer (88) and the first interlayer insulating layer (87) and is longer than the lower via electrode (911) and the upper via electrode (912).

### Supplementary Note 1-9

The semiconductor device (1A, 1B) of Supplementary Note 1-7 or 1-8, wherein the at least one first via electrode (91) includes a plurality of first via electrodes (91), and the at least one second via electrode (93) includes a plurality of second via electrodes (93), and
wherein in a plan view, the first isolation trench (15) includes a first region (94) in which the plurality of first via electrodes (91) are selectively arranged, and a second region (95) which is separated from the first region (94) in a longitudinal direction of the first isolation trench (15) and in which the plurality of second via electrodes (93) are selectively arranged.

### Supplementary Note 1-10

The semiconductor device (1A, 1B) of any one of Supplementary Notes 1-1 to 1-9, wherein the at least one second isolation conductor (29) is fixed at a third potential (V₃) between a first potential (V₁) of the first isolation conductor (28) and a second potential (V₂) of the device region (10, 11).

### Supplementary Note 1-11

The semiconductor device (1A, 1B) of any one of Supplementary Notes 1-1 to 1-10, wherein the semiconductor chip (2) includes:
a first impurity region (6) of a first conductivity type formed at the second main surface (4);
a second impurity region (7) of a second conductivity type formed at the first main surface (3); and
a buried region (8) of the second conductivity type buried between the first impurity region (6) and the second impurity region (7),
wherein the first isolation trench (15) penetrates from the first main surface (3) through the second impurity region (7) and the buried region (8) and has a bottom (18) in the first impurity region (6), and
wherein the at least one second isolation conductor (29) is sandwiched between the first isolation conductor (28) and both the second impurity region (7) and the buried region (8) in a lateral direction along the first main surface (3).

### Supplementary Note 1-12

The semiconductor device (1A, 1B) of Supplementary Note 1-11, wherein the semiconductor chip (2) further includes a sinker region (59) of the second conductivity type that is formed along a side wall of the first isolation trench (15) in the second impurity region (7) and has a concentration higher than a concentration of the second impurity region (7).

### Supplementary Note 1-13

The semiconductor device (1A, 1B) of Supplementary Note 1-11 or 1-12, wherein the first impurity region (6) includes a substrate (6a) of the first conductivity type and an epitaxial layer (6b) of the first conductivity type having a concentration lower than a concentration of the substrate (6a),
wherein a lower end (40) of the at least one second isolation conductor (29) is disposed within the substrate (6a).

### Supplementary Note 1-14

The semiconductor device (1A, 1B) of any one of Supplementary Notes 1-11 to 1-13, wherein the inner insulating film (25) has an opening (9) at the bottom (18) of the first isolation trench (15), and
wherein the first isolation conductor (28) is electrically connected to the first impurity region (6) via the opening (9).

### Supplementary Note 1-15

A method of manufacturing a semiconductor device (1A, 1B), including:
forming an annular first trench (106) to partition a device region (10, 11) at a first main surface (101) of a semiconductor wafer (100) including the first main surface (101) and a second main surface (102) opposite to the first main surface (101);
forming an outer insulating film (24) at an inner wall (19, 18) of the first trench (106) and forming a recess (107), which is defined by the outer insulating film (24), in the first trench (106);
forming a first conductor layer (108) over the outer insulating film (24) within the recess (107) while leaving the recess (107) in the first trench (106);
forming an outer isolation conductor (29) formed of the first conductor layer (108) remaining at a side wall (19) of the first trench (106) and forming a second trench (109) defined by the outer isolation conductor (29) by selectively etching a portion of the first conductor layer (108) on a bottom wall (18) of the first trench (106) and a portion of the outer insulating film (24) on the bottom wall (18) of the first trench (106);
forming an inner insulating film (25) at a portion of the outer isolation conductor (29) of an inner wall (21, 41, 43) of the second trench (109) and a portion of the semiconductor wafer (100); and
forming an inner isolation conductor (28) by burying a conductive material (110) in the second trench (109).

According to this method, it is possible to provide a semiconductor device (1A, 1B) that may improve a breakdown voltage in the lateral direction along the first main surface (3) of the semiconductor chip (2).

### Supplementary Note 1-16

The method of Supplementary Note 1-15, wherein the semiconductor wafer (100) includes:
a first impurity region (6) of a first conductivity type formed at the second main surface (102);
a second impurity region (7) of a second conductivity type formed at the first main surface (101); and
a buried region (8) of the second conductivity type buried between the first impurity region (6) and the second impurity region (7),
wherein the first trench (106) is formed from the first main surface (101) through the second impurity region (7) and the buried region (8) so that a bottom (18) of the first trench (106) reaches the first impurity region (6).

### Supplementary Note 1-17

The method of Supplementary Note 1-15 or 1-16, wherein the first conductor layer (108) is formed to integrally cover the inner wall (19, 18) of the first trench (106) and the first main surface (101) of the semiconductor wafer (100), and
wherein in the forming the second trench (109), an inclined wall (44) that connects an outer wall (42) of the outer isolation conductor (29) to an inner wall (41) of the outer isolation conductor (29) and is inclined downward from the outer wall (42) of the outer isolation conductor (29) toward the inner wall (41) of the outer isolation conductor (29) is formed at a top (43) of the outer isolation conductor (29) by etching a portion of the first conductor layer (108) on the first main surface (101) and then selectively etching an upper portion of the first conductor layer (108) on the inner wall (19) of the first trench (106).

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A semiconductor device comprising:
a semiconductor chip including a first main surface and a second main surface opposite to the first main surface; and
an element isolation portion formed at the first main surface of the semiconductor chip and partitioning a device region,
wherein the element isolation portion includes:
a first isolation trench formed at the first main surface of the semiconductor chip;
an isolation insulating film formed at an inner wall of the first isolation trench; and
an isolation conductor buried in the first isolation trench via the isolation insulating film,
wherein the isolation conductor includes:
a first isolation conductor formed at a central portion of the first isolation trench; and
at least one second isolation conductor formed at a side of the first isolation conductor with an inner insulating film, which is a portion of the isolation insulating film, interposed between the first isolation conductor and the at least one second isolation conductor,
wherein the at least one second isolation conductor includes an inner wall in contact with the inner insulating film and an outer wall opposite to the inner wall, and
wherein a top of the at least one second isolation conductor includes an inclined wall that connects the outer wall to the inner wall and is inclined downward from the outer wall toward the inner wall.

2. The semiconductor device of claim 1, further comprising: at a surface layer of the first main surface of the semiconductor chip,
a second isolation trench formed to cross a boundary between the first isolation conductor and the at least one second isolation conductor along the first main surface; and
a buried insulator buried in the second isolation trench,
wherein the first isolation conductor includes a top side wall facing the inclined wall of the at least one second isolation conductor in a direction along the first main surface, and a top bottom wall extending from a lower end of the top side wall toward the at least one second isolation conductor.

3. The semiconductor device of claim 2, wherein the inclined wall of the at least one second isolation conductor includes a lower end adjacent to an end of the top bottom wall of the first isolation conductor with the inner insulating film interposed between the first isolation conductor and the at least one second isolation conductor.

4. The semiconductor device of claim 1, wherein the at least one second isolation conductor includes a pair of second isolation conductors,
wherein the isolation conductor includes the pair of second isolation conductors separated from each other in a cross-sectional view, and
wherein the pair of second isolation conductors sandwich the first isolation conductor in a lateral direction along the first main surface, and the pair of second isolation conductors is a pair of side walls that cover the first isolation conductor from a lower end of the first isolation conductor to a top of the first isolation conductor.

5. The semiconductor device of claim 4, wherein a bottom of the first isolation trench includes an uneven surface including a concave portion at the central portion and a pair of convex portions at both sides adjacent to the central portion,
wherein the lower end of the first isolation conductor is buried in the concave portion, and
wherein the pair of side walls are supported by the pair of convex portions.

6. The semiconductor device of claim 5, wherein a depth from a top surface of the convex portions to a bottom surface of the concave portion is 1/10 or less of a width of the first isolation trench.

7. The semiconductor device of claim 1, further comprising:
an interlayer insulating layer formed over the first main surface of the semiconductor chip;
at least one first via electrode buried in the interlayer insulating layer and connected to a top of the first isolation conductor; and
at least one second via electrode buried in the interlayer insulating layer and connected to the top of the at least one second isolation conductor,
wherein a second width of the at least one second via electrode is wider than a first width of the at least one first via electrode.

8. The semiconductor device of claim 7, wherein the interlayer insulating layer includes a first interlayer insulating layer and a second interlayer insulating layer formed over the first interlayer insulating layer and further includes a first wiring layer formed between the first interlayer insulating layer and the second interlayer insulating layer,
wherein the at least one first via electrode is separated into a lower via electrode buried in the first interlayer insulating layer and an upper via electrode buried in the second interlayer insulating layer, with the first wiring layer interposed between the lower via electrode and the upper via electrode, and
wherein the at least one second via electrode includes a long via electrode that is buried through the second interlayer insulating layer and the first interlayer insulating layer and is longer than the lower via electrode and the upper via electrode.

9. The semiconductor device of claim 7, wherein the at least one first via electrode includes a plurality of first via electrodes, and the at least one second via electrode includes a plurality of second via electrodes, and
wherein in a plan view, the first isolation trench includes a first region in which the plurality of first via electrodes are selectively arranged, and a second region which is separated from the first region in a longitudinal direction of the first isolation trench and in which the plurality of second via electrodes are selectively arranged.

10. The semiconductor device of claim 1, wherein the at least one second isolation conductor is fixed at a third potential between a first potential of the first isolation conductor and a second potential of the device region.

11. The semiconductor device of claim 1, wherein the semiconductor chip includes:
a first impurity region of a first conductivity type formed at the second main surface;
a second impurity region of a second conductivity type formed at the first main surface; and
a buried region of the second conductivity type buried between the first impurity region and the second impurity region,
wherein the first isolation trench penetrates from the first main surface through the second impurity region and the buried region and has a bottom in the first impurity region, and
wherein the at least one second isolation conductor is sandwiched between the first isolation conductor and both the second impurity region and the buried region in a lateral direction along the first main surface.

12. The semiconductor device of claim 11, wherein the semiconductor chip further includes a sinker region of the second conductivity type that is formed along a side wall of the first isolation trench in the second impurity region and has a concentration higher than a concentration of the second impurity region.

13. The semiconductor device of claim 11, wherein the first impurity region includes:
a substrate of the first conductivity type; and
an epitaxial layer of the first conductivity type having a concentration lower than a concentration of the substrate,
wherein a lower end of the at least one second isolation conductor is disposed within the substrate.

14. The semiconductor device of claim 11, wherein the inner insulating film has an opening at the bottom of the first isolation trench, and
wherein the first isolation conductor is electrically connected to the first impurity region via the opening.

15. A method of manufacturing a semiconductor device, comprising:
forming an annular first trench to partition a device region at a first main surface of a semiconductor wafer including the first main surface and a second main surface opposite to the first main surface;
forming an outer insulating film at an inner wall of the first trench and forming a recess, which is defined by the outer insulating film, in the first trench;
forming a first conductor layer over the outer insulating film within the recess while leaving the recess in the first trench;
forming an outer isolation conductor formed of the first conductor layer remaining at a side wall of the first trench and forming a second trench defined by the outer isolation conductor, by selectively etching a portion of the first conductor layer on a bottom wall of the first trench and a portion of the outer insulating film on the bottom wall of the first trench;
forming an inner insulating film at a portion of the outer isolation conductor of an inner wall of the second trench and a portion of the semiconductor wafer; and
forming an inner isolation conductor by burying a conductive material in the second trench.

16. The method of claim 15, wherein the semiconductor wafer includes:
a first impurity region of a first conductivity type formed at the second main surface;
a second impurity region of a second conductivity type formed at the first main surface; and
a buried region of the second conductivity type buried between the first impurity region and the second impurity region,
wherein the first trench is formed from the first main surface through the second impurity region and the buried region so that a bottom of the first trench reaches the first impurity region.

17. The method of claim 15, wherein the first conductor layer is formed to integrally cover the inner wall of the first trench and the first main surface of the semiconductor wafer, and
wherein in the forming the second trench, an inclined wall that connects an outer wall of the outer isolation conductor to an inner wall of the outer isolation conductor and is inclined downward from the outer wall of the outer isolation conductor toward the inner wall of the outer isolation conductor is formed at a top of the outer isolation conductor by etching a portion of the first conductor layer on the first main surface and then selectively etching an upper portion of the first conductor layer on the inner wall of the first trench.
